(19) United States
(12) Patent Application Publication
(10) Pub. No.: US 2020/0324570 A1
(43) Pub. Date: Oct. 15, 2020

(54) DECORATIVE PRODUCT

(71) Applicant: TOYODA GOSEI CO., LTD., Kiyosu-shi, Aichi-ken (JP)

(72) Inventors: Shintarou OKAWA, Kiyosu-shi, Aichi-ken (JP); Hiroaki ANDO, Kiyosu-shi, Aichi-ken (JP)

(21) Appl. No.: 16/617,910

(22) PCT Filed: Jun. 14, 2018
(86) PCT No.: PCT/JP2018/022743

§ 371 Date: Nov. 27, 2019

(30) Foreign Application Priority Data
Jun. 29, 2017 (JP) 2017-127268

(51) Int. Cl. B44F 1/04; C23C 14/34; C23C 14/18; C03C 17/09; C22C 27/04

(52) U.S. Cl. CPC B44F 1/045; C23C 14/34; C23C 14/18; B44C 3/02; C22C 27/04; C03C 2217/27; C03C 2218/154; C03C 17/09

(57) ABSTRACT

A decorative product includes a decorative layer containing nickel, chromium, and molybdenum as constituent components. The molybdenum content in the decorative layer is 50 atm % or less. The total content of nickel, chromium, and molybdenum in the decorative layer is 95 atm % or more.

### CROSS REFERENCE TO RELATED APPLICATIONS

This application is a U.S. national stage application of International Application No. PCT/JP2018/022743, filed on Jun. 14, 2018, which claims priority to Japanese Patent Application No. 2017-127268 filed on Jun. 29, 2017, the contents of which are incorporated herein by reference.

### BACKGROUND

The present invention relates to a decorative product. More specifically, the present invention relates to a decorative product employed as a car accessory.

An alloy containing nickel, chromium, and molybdenum as constituent elements (for example, Hastelloy alloy) has high corrosion resistance against acids and alkalis and excellent heat resistance, and hence is widely employed as parts that require corrosion resistance and heat resistance, such as chemical plant piping or jet engine combustion chambers. For example, Patent Document 1 discloses a technique in which the above alloy is employed as a laminated wiring film laminated on the substrate of an electronic component, thereby providing an electronic component having excellent moisture resistance and oxidation resistance while maintaining a low electric resistance value.

### PRIOR ART DOCUMENT

### Patent Document

Patent Document 1: Japanese Laid-Open Patent Publication No. 2014-185393

### SUMMARY

To improve corrosion resistance and heat resistance, it is conceivable to employ an alloy containing nickel, chromium, and molybdenum as constituent elements to a decorative layer for adding glitter to a decorative product such as a car accessory. Unlike pipes and electronic components, decorative products are used in open spaces that are visible to the human eye. Therefore, when the alloy is employed as a decorative layer of a decorative product, the decorative layer is required to have a reflectance that allows visual recognition of glitter and excellent weather resistance.

An objective of the present invention is to provide a decorative product having a decorative layer having not only excellent weather resistance but also high surface reflectance.

To achieve the foregoing objective, and in accordance with one aspect of the present invention, a decorative product is provided that includes a decorative layer containing nickel, chromium, and molybdenum as constituent components. A molybdenum content in the decorative layer is 50 atm % or less. A total content of nickel, chromium, and molybdenum in the decorative layer is 95 atm % or more.

In the above-described invention, a nickel content in the decorative layer is 10 atm % or more and 75 atm % or less. A chromium content in the decorative layer is 10 atm % or more and 60 atm % or less. The molybdenum content in the decorative layer is 15 atm % or more and 50 atm % or less.

In the above-described invention, the decorative layer is a half mirror layer that transmits a part of incident light and reflects a part of incident light.

In the above-described invention, a thickness of the decorative layer is 20 nm or more and 100 nm or less.

The present invention provides a decorative product comprising a decorative layer having not only excellent weather resistance and but also high surface reflectance.

### BRIEF DESCRIPTION OF THE DRAWINGS

FIG. 1 is a partial cross-sectional view of a decorative product of the present embodiment.

FIG. 2 shows the composition of nickel, chromium, and molybdenum in the decorative layer.

FIG. 3 shows the measurement results of the reflectance of the decorative layer surface.

### DETAILED DESCRIPTION OF THE PREFERRED EMBODIMENTS

A decorative product according an embodiment of the present invention will now be described. In the embodiment, the decorative product is employed as an exterior component for a vehicle.

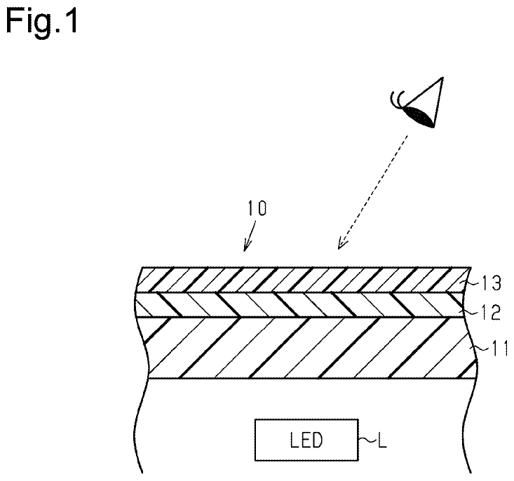

As shown in FIG. 1, an exterior component 10 of the present embodiment has a structure in which a substrate 11, a decorative layer 12 having glitter; and a protective layer 13 for protecting the decorative layer 12 are sequentially laminated, and is attached to the vehicle as a cover member that covers a light emitting part L. The light emitting part L is composed of an LED lamp or the like. The exterior component 10 functions as a half mirror. That is, from the viewpoint on the side of the protective layer 13, the exterior component 10 exhibits a bright appearance based on the decorative layer 12 when the light emitting part L does not emit light, and transmits light from the light emitting part L when the light emitting part L emits light.

The substrate 11 is composed of transparent plastic or transparent glass. The transparent plastic is not particularly limited as long as it is colorless and transparent or colored and transparent, and conventionally known plastics can be used. Examples of the transparent plastic include thermoplastic plastics such as polyethylene plastic, polypropylene plastic, polyethylene terephthalate plastic, vinyl chloride plastic, polystyrene plastic, acrylonitrile/butadiene/styrene copolymer (ABS) plastic, acrylic plastic, polyamide plastic, and polycarbonate plastic. Examples of the transparent plastic also include thermosetting plastics such as phenolic plastic, melamine plastic, unsaturated polyester plastic, and epoxy plastic. The transparent glass is not particularly limited as long as it is colorless and transparent or colored and transparent, and examples thereof include alkali glass and alkali-free glass.

The decorative layer 12 is a metal film made of an alloy containing nickel, chromium, and molybdenum as constituent components. The decorative layer 12 has a thickness of 100 nm or less.

Particularly, nickel functions as a base material for an alloy constituting the decorative layer 12. The nickel content in the decorative layer 12 is preferably 10 to 75 atm %, and more preferably 10 to 55 atm %. Setting the nickel content within the above range can form the stable decorative layer 12.

When the numerical range is referred to as A to B, it is A or more and B or less.

Particularly, chromium improves the weather resistance of the decorative layer 12 and improves the corrosion resistance against acids and alkalis. The chromium content in the decorative layer 12 is preferably 10 to 60 atm %, and more preferably 30 to 60 atm %. Setting the chromium content within the above range improves the water resistance and corrosion resistance of the decorative layer. In addition, the corrosion resistance against salt content is improved, and hence the tolerance against the snow melting salt used in cold regions is improved.

Molybdenum particularly affects the weather resistance of the decorative layer 12. The molybdenum content in the decorative layer 12 is 50 atm % or less. Setting the molybdenum content to 50 atm % or less improves the weather resistance, particularly the water resistance of the decorative layer 12. Molybdenum affects the color tone (brightness) of the decorative layer 12. High molybdenum content increases the reflectance of the decorative layer 12. Therefore, increasing the molybdenum content can add a slightly bluish and deep color tone to the decorative layer 12, which is close to the color tone of hexavalent chromium plating, general metal plating. These colors are particularly preferred by users as cool looking decorations. Therefore, the molybdenum content in the decorative layer 12 is preferably 15 atm % or more, and more preferably 20 atm % or more.

The decorative layer 12 may contain components other than nickel, chromium, and molybdenum as long as the total content of nickel, chromium, and molybdenum is in the range of 95 atm % or more. Examples of other components include metal elements such as iron, cobalt, tungsten, manganese, and silicon.

The thickness of the decorative layer 12 is preferably 10 to 100 nm, more preferably 20 to 60 nm, and still more preferably 20 to 40 nm. Setting the thickness of the decorative layer 12 to 100 nm or less causes the decorative layer 12 to become a half mirror layer that reflects a part of incident light and transmits a part of incident light. In addition, the thickness of the decorative layer 12 is in the range of 10 to 100 nm, suppressing the occurrence of cracks in the decorative layer 12.

The transmittance of the decorative layer 12 is preferably 10 to 50%, and more preferably 10 to 20%. The reflectance of the decorative layer 12 is preferably 48.0% or more, and more preferably 48.6% or more. In this case, it is easy to obtain a glitter appearance equivalent to that of a hexavalent chromium plating layer.

Examples of the method of forming the decorative layer 12 include known thin film forming methods such as sputtering and metal vapor deposition. For example, when the decorative layer 12 is formed by sputtering, the substrate 11 is held in the chamber of the sputtering apparatus. The pressure in the chamber is reduced to a predetermined pressure, and then argon gas as a sputtering gas is injected into the chamber. A voltage is applied to excite the argon gas, and the target material particles are ejected by argon ions to adhere and deposit the target material particles onto the surface of the substrate 11. At this time, the decorative layer 12 may be formed by a single sputtering using a target material containing nickel, chromium, and molybdenum as constituent components. Alternatively, the decorative layer 12 may be formed by repeatedly performing sputtering using a plurality of target materials having a single component while changing the target material.

The protective layer 13 is not particularly limited, and a layer made of a conventionally known transparent plastic is appropriately applicable. Examples of the plastic constituting the protective layer 13 include acrylic plastics such as acrylic urethane. For example, the thickness of the protective layer 13 is preferably 10 to 30 nm, and more preferably 15 to 25 nm.

The decorative product of the present embodiment has the following advantages.

(1) The decorative product of the present embodiment comprises the decorative layer 12 containing nickel, chromium, and molybdenum as constituent components. The molybdenum content in the decorative layer 12 is 50 atm % or less. Therefore, the decorative layer 12 having excellent weather resistance and water resistance can be obtained.

(2) High molybdenum content in the decorative layer 12 increases the reflectance of the decorative layer 12. Therefore, a suitable brightness can be added to the surface of the decorative layer 12. Brightness equivalent to that of a conventional hexavalent chromium plating layer can be obtained, allowing the glitter appearance of the decorative product to be improved.

(3) High molybdenum content in the decorative layer 12 can add a slightly bluish and deep color tone peculiar to molybdenum to the surface of the decorative layer 12. Such a color tone is close to the color tone of the conventional hexavalent chromium plating layer, which can provide a color tone equivalent to that of the hexavalent chromium plating layer. A slightly bluish and deep color tone can be added to the decorative product, which can provide a decorative product with a cool looking appearance.

(4) The decorative product of the present embodiment comprises the decorative layer 12 containing nickel, chromium, and molybdenum as constituent components. The total content of nickel, chromium, and molybdenum in the decorative layer 12 is 95 atm % or more. Typical examples of the metal element other than molybdenum which can be a solid solution in nickel-chromium alloy include iron and tungsten. However, the increase in the iron content reduces the corrosion resistance in a reducing atmosphere, and the increase in the tungsten content tends to reduce the brightness (L value). Therefore, the total content of iron and tungsten, which are components other than nickel, chromium, and molybdenum, is set to a predetermined value or less, providing the decorative layer 12 having excellent corrosion resistance and suitable brightness.

The above structure makes it easy to form the decorative layer 12. For example, when the decorative layer 12 is formed by sputtering, in order to increase the content of the specific component, it is necessary to increase the content of the specific component in the target solid solution depending on the sputtering rate. However, the sputtering rate of tungsten is lower than those of nickel, chromium, and molybdenum. In addition, the melting point of tungsten is higher than the melting points of nickel, chromium, and molybdenum. It is difficult to form a solid solution with a high content of tungsten. Limiting the content of tungsten in the decorative layer 12 makes it easy to form the solid solution. Therefore, the decorative layer 12 is easily formed.

(5) The chromium content in the decorative layer 12 is 10 to 60 atm %. Therefore, a decorative product having excellent water resistance, corrosion resistance against acids and alkalis, and resistance against snow melting salt can be obtained.

The above embodiment may be modified as follows. In addition, the following modification examples may be combined.

In the decorative product of the above embodiment, the case where the decorative layer is formed by the sputtering has been described, but the decorative layer may be formed by a metal vapor deposition. In this case as well, the decorative layer becomes a half mirror layer by controlling the thickness of the decorative layer to 10 to 100 nm.

The decorative product of the above embodiment functions as a half mirror, but the decorative product may be employed in applications that do not require the function as a half mirror. In this case, the thickness of the decorative layer 12 may exceed 100 nm.

In the decorative product of the above embodiment, a protective layer 13 is laminated on the decorative layer, but the protective layer 13 can be omitted. In addition, a layer other than the protective layer 13 may be provided as long as the glitter and weather resistance of the decorative layer 12 are not impaired.

The decorative product is not limited to an exterior component for a vehicle, and may be employed as an interior component for a vehicle or may be employed in applications other than a vehicle.

A technical concept obtained from the above embodiment will now be described.

(A) The nickel content in the decorative layer is 10 to 55 atm %, the chromium content in the decorative layer is 30 to 60 atm %, and the molybdenum content in the decorative layer is 20 to 50 atm %.

Setting the contents of nickel, chromium, and molybdenum within the above ranges provides a decorative product comprising a decorative layer having excellent weather resistance and high surface reflectance.

### EXAMPLES

The above embodiment is described more specifically with reference to Examples.

### Test 1

A decorative product having a decorative layer containing nickel, chromium, and molybdenum was produced. More specifically, the decorative layer was formed so as to comprise a plurality of portions having different contents of nickel, chromium, and molybdenum. The reflectance of the decorative product was measured.

Test Sample

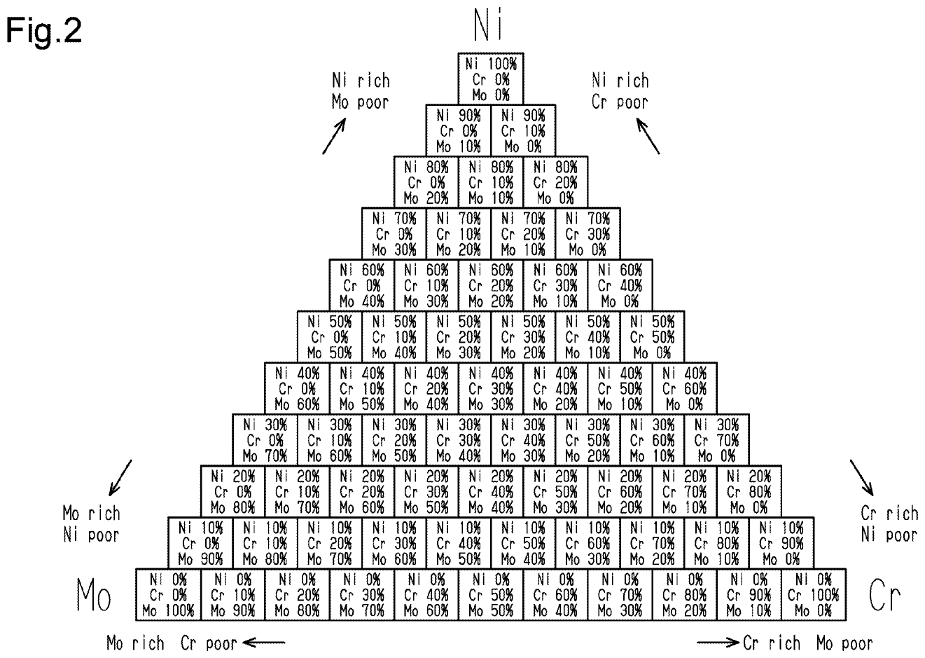

A test sample having an alkali-free glass base material and a decorative layer formed on the surface of the alkali-free glass base material was used. The decorative layer was formed by adhering and depositing nickel, chromium, and molybdenum onto the surface of the alkali-free glass base material. The decorative layer was formed by using a combinatorial sputtering apparatus (CMS-6420, manufactured by Comet, Inc.) so as to follow the composition distribution shown in FIG. 2. The thickness of the decorative layer was set to 20 nm. As shown in FIG. 2, the decorative layer of the test sample was formed so that the nickel content was higher as the composition was closer to the first vertex of the triangle (the vertex on the upper side in FIG. 2), the chromium content was higher as the composition was closer to the second vertex (the vertex on the lower right side in FIG. 2), and the molybdenum content was higher as the composition was closer to the third vertex (the vertex on the lower left side in FIG. 2).

Reflectance Measurement

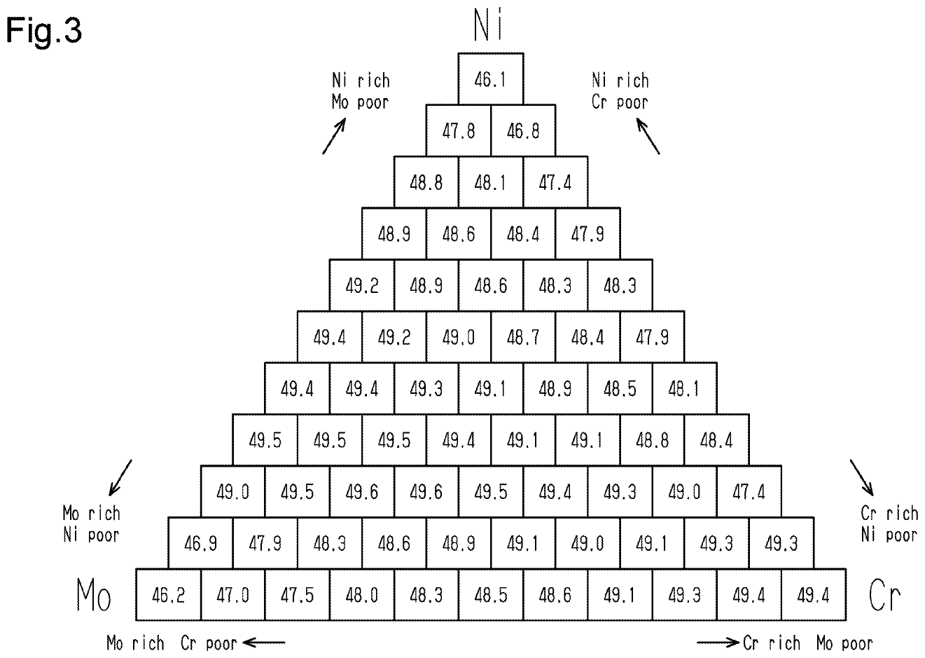

The reflectance of each portion having a different composition in the decorative layer of the test sample was measured. The measurement of the reflectance was performed using a multichannel spectrometer (manufactured by Otsuka Electronics Co., Ltd.: MCPD-3700) with moving the measurement point on a XY table. The results are shown in FIG. 3.

As shown in FIG. 3, the reflectance was confirmed to tend to be high as the chromium content was higher. In addition, the reflectance of a portion containing only two components or only one component of the three components or a portion containing molybdenum at an extremely high concentration (80 atm % or more) was confirmed to tend to be low. These results found that a decorative product having a high reflectance was obtained by forming a decorative layer containing three components of nickel, chromium, and molybdenum and having a molybdenum content of 70 atm % or less.

Test 2

Decorative products of test product 1 and test product 2 having decorative layers with different content ratios of nickel, chromium, and molybdenum were produced. Each of the test product 1 and the test product 2 was formed so as to satisfy the conditions under which the excellent reflectance in the test 1 was confirmed. That is, each of the test product 1 and the test product 2 contained three components of nickel, chromium, and molybdenum. The molybdenum content in each of the test product 1 and the test product 2 was set to 70 atm % or less. The initial adhesion and the weather resistance of the test product 1 and the test product 2 were evaluated.

Test Product 1

A decorative layer was formed on the surface of a base material formed from polycarbonate plastic by a sputtering apparatus (i-miller II, manufactured by Shibaura Mechatronics Co., Ltd.) using a target having nickel, chromium, and molybdenum as constituent components. The thickness of the decorative layer was set to 30 nm. The composition of the decorative layer was measured and found to be 50 atm % of nickel, 20 atm % of chromium, and 30 atm % of molybdenum. A protective layer having a thickness of 20 nm made of acrylic urethane plastic was formed on the decorative layer, and this was designated as the test product 1.

Test Product 2

A decorative layer was formed on the surface of a base material formed from polycarbonate plastic in the same manner as in the test product 1, except that a target having a different composition was used. In the same manner as the test product 1, the thickness of the decorative layer was set to 30 nm. The composition of the decorative layer was measured and found to be 20 atm % of nickel, 20 atm % of chromium, and 60 atm % of molybdenum. A protective layer having a thickness of 20 nm made of acrylic urethane plastic was formed on the decorative layer, and this was designated as the test product 2.

Initial Adhesion Test

An initial adhesion test was performed on the test product 1 and test product 2 by the following method to evaluate the initial adhesion of the decorative layer.

The initial adhesion test was performed by a cross-cut test of JIS K 5400. Specifically, a grid of 100 squares in total was formed on each surface of the test product 1 and test product 2, with 10 squares each having a size of 2 mm square arranged in rows and columns. In each of the test product 1 and the test product 2, the number of squares peeled off when the adhesive tape attached to the surface was peeled was measured.

The results are shown in Table 1.

### Water Resistance Test

A water resistance test was performed on the test product 1 and test product 2 by the following method to evaluate the weather resistance of the decorative layer.

In the water resistance test, the test product 1 and test product 2 immersed in warm water at 40° C. were evaluated. The test product 1 and test product 2 were immersed in warm water at 40° C. for 240 hours. Thereafter, the test product 1 and test product 2 were taken out from the warm water, and the surface color difference ΔE and the gloss retention ratio GR of the surface were measured, and a cross-cut test similar to the initial adhesion test of the test 1 was performed.

The surface color difference ΔE was measured based on the method of JIS Z 8730. The surface color difference ΔE was calculated as a geometric mean of differences in L*a*b* values by comparing the object color L*a*b* values on the surface of the decorative layer before and after the water resistance test. A surface color difference ΔE of 3.0 or less was accepted.

The gloss retention ratio GR of the surface of the decorative layer was measured based on the method of JIS K 5600-4-7. A gloss retention ratio GR of 80% or more was accepted.

The results are shown in Table 1.

TABLE 1

| | | Evaluation Results | |
|---|---|---|---|
| Evaluation Items | | Test Product 1 | Test Product 2 |
| Initial | Cross-Cut Test | Peeling Occurrence 0/100 | Peeling Occurrence 0/100 |
| Adhesion Test | | | |
| Water | Surface Color | 0.32 | Not Measurable |
| Resistance | Difference ΔE | | |
| Test | Surface Gloss | 98.3% | Not Measurable |
| | Retention Ratio | | |
| | GR | | |
| | Cross-Cut Test | Peeling Occurrence 0/100 | Not Measurable |
| | | | (Decorative Layer |
| | | | Disappearance) |

As shown in Table 1, good results were obtained in both the initial adhesion test and the water resistance test in the test product 1 comprising the decorative layer containing 50 atm % of nickel, 20 atm % of chromium, and 30 atm % of molybdenum. On the other hand, in the test product 2 comprising the decorative layer containing 20 atm % of nickel, 20 atm % of chromium, and 60 atm % of molybdenum, the result of the initial adhesion test was good. However, in the water resistance test, the decorative layer disappeared during the test, and measurement itself failed. In the test product 2, it is assumed that high content of molybdenum made it easy to dissolve the decorative layer in water, and the decorative layer dissolved and disappeared in warm water.

Test 3

For the test product 1, in which the result of the water resistance test was good in Test 2, a heat resistance test, a moisture resistance test, an accelerated weather resistance test, a snow melting salt corrosion resistance test, and an outdoor exposure test were performed, and the weather resistance was evaluated.

Heat Resistance Test

The test product 1 was subjected to a heat resistance test by the following method to evaluate the weather resistance of the decorative layer. In the heat resistance test, the test product 1 was put in a thermostatic bath at 80° C. and taken out after 240 hours. Thereafter, in the same manner as in Test 2, the surface color difference ΔE and the gloss retention ratio GR of the surface were measured, and a cross-cut test similar to the initial adhesion test in Test 1 was performed.

The results are shown in Table 2.

### Moisture Resistance Test

The test product 1 was subjected to a moisture resistance test by the following method to evaluate the weather resistance of the decorative layer.

In the moisture resistance test, the test product 1 was put in a thermostatic bath at 50° C. and a humidity of 95%, and was taken out after 240 hours. Thereafter, in the same manner as in Test 2, the surface color difference ΔE and the gloss retention ratio GR of the surface were measured, and a cross-cut test similar to the initial adhesion test in Test 1 was performed.

The results are shown in Table 2.

### Accelerated Weather Resistance Test

The test product 1 was subjected to an accelerated weather resistance test by the following method to evaluate the weather resistance of the decorative layer.

In the accelerated weather resistance test, the test product 1 was irradiated with a xenon lamp so that the integrated light amount was 500 MJ. Thereafter, in the same manner as in Test 2, the surface color difference ΔE and the gloss retention ratio GR of the surface were measured, and a cross-cut test similar to the initial adhesion test in Test 1 was performed.

The results are shown in Table 2.

### Snow Melting Salt Corrosion Resistance Test

The test product 1 was evaluated based on the CASS test method. More specifically, an aqueous solution obtained by adding cupric chloride and acetic acid to 5% NaCl was continuously sprayed onto the surface of the test product 1 for 80 hours. Thereafter, in the same manner as in Test 2, the surface color difference ΔE was measured, and the presence or absence of appearance abnormality was observed, and a cross-cut test similar to the initial adhesion test in Test 1 was performed.

The results are shown in Table 2.

### Outdoor Exposure Test

The test product 1 was subjected to an outdoor exposure test by the following method to evaluate the weather resistance of the decorative layer.

In the outdoor exposure test, the test product 1 was left outdoors in Miyakojima, Okinawa for half a year. Thereafter, in the same manner as in Test 2, the surface color difference ΔE was measured, and the presence or absence of appearance abnormality was observed, and a cross-cut test similar to the initial adhesion test in Test 1 was performed.

The results are shown in Table 2.

TABLE 2

| Evaluation Items | | Evaluation Results |
|---|---|---|
| Heat Resistance Test | Surface Color Difference ΔE | 0.1 |
| | Surface Gloss Retention Ratio | 99.3% |
| | GR | |
| | Cross-Cut Test | Peeling Occurrence 0/100 |
| Moisture Resistance | Surface Color Difference ΔE | 0.12 |
| Test | Surface Gloss Retention Ratio | 99.5% |
| | GR | |
| | Cross-Cut Test | Peeling Occurrence 0/100 |
| Accelerated Weather | Surface Color Difference ΔE | 1.33 |
| Resistance Test | Surface Gloss Retention Ratio | 80.2% |
| | GR | |
| | Cross-Cut Test | Peeling Occurrence 0/100 |
| Snow Melting Salt | Surface Color Difference ΔE | 0.48 |
| Corrosion Resistance | Presence or Absence of | No Abnormality |
| Test | Appearance Abnormality | |
| | Cross-Cut Test | Peeling Occurrence 0/100 |
| Outdoor Exposure | Surface Color Difference ΔE | 1.02 |
| Test | Presence or Absence of | No Abnormality |
| | Appearance Abnormality | |
| | Cross-Cut Test | No Occurrence of Peeling at Cross- |
| | | Cut Portions |

As shown in Table 2, the test product 1 having a decorative layer containing 50 atm % of nickel, 20 atm % of chromium, and 30 atm % of molybdenum provided good results of all of the heat resistance test, the moisture resistance test, the accelerated weather resistance test, the snow melting salt corrosion resistance test, and the outdoor exposure test.

It is found from the results of tests 1 to 3 that a decorative product having a reflectance that allows visual recognition of glitter and excellent weather resistance can be obtained by forming the decorative layer that contains nickel, chromium, and molybdenum as constituent components wherein the molybdenum content is a specific value (50 atm % or less) or less.

1. A decorative product comprising a decorative layer containing nickel, chromium, and molybdenum as constituent components, wherein
a molybdenum content in the decorative layer is 50 atm % or less, and
a total content of nickel, chromium, and molybdenum in the decorative layer is 95 atm % or more.

2. The decorative product according to claim 1, wherein
a nickel content in the decorative layer is 10 atm % or more and 75 atm % or less,
a chromium content in the decorative layer is 10 atm % or more and 60 atm % or less, and
the molybdenum content in the decorative layer is 15 atm % or more and 50 atm % or less.

3. The decorative product according to claim 1, wherein the decorative layer is a half mirror layer that transmits a part of incident light and reflects a part of incident light.

4. The decorative product according to claim 3, wherein a thickness of the decorative layer is 20 nm or more and 100 nm or less.
